(19) United States
(12) Patent Application Publication
(10) Pub. No.: US 2008/0121905 A1
(43) Pub. Date: May 29, 2008

(54) Planar Flip & Small Chips Integrated LED Chip and its Manufacture Method

(76) Inventor: Wei-Kuo Wu, Zhuhai (CN)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/770,892

(22) Filed: Jun. 29, 2007

(30) Foreign Application Priority Data
Jun. 30, 2006 (CN) 2006/0036154.1

(51) Int. Cl. H01L 33/00

(52) U.S. Cl. 257/93; 438/28; 257/E33.056; 257/E33.012

(57) ABSTRACT

A planar flip bonded & small chips integrated LED chip comprising a plurality of LED bare chips and silicon substrates; the LED bare chip comprising a substrate, a N type epitaxial layer, and a P type epitaxial layer; the silicon substrate having two separated deposited metal layers facing each LED bare chip; the P type epitaxial layer and the N type epitaxial layer being separately flip bonded on the metal layers via solder balls; and is characterized in that: the contact areas of the metal layers and the silicon substrate separately has a doped isolating layer, an isolating layer is disposed between the metal layer corresponding to each LED bare chip and the silicon substrate, the plurality of LED bare chips are connected via the metal layers and forms an anode electrode and a cathode electrode.

### BACKGROUND OF THE INVENTION

1. Field of the Invention

The present invention relates to a planar flip bonded & Small Chips integrated LED chip and its manufacture method.

2. Description of the Related Art

Flip chip technology is one of the most advance micro electronic package technologies. It includes chip connecting technology and chip bonding technology, and it improves the circuit assemble density. Among all surfaces assemble technologies, the flip chip technology can provide the smallest, thinnest package, which is more and more popular for the modem electronic devices. A flip bonded LED means the LED bare chip is flip assembled on the silicon substrate. Prior art flip bonded LEDs utilize large size power LED, which requires higher cost. Furthermore, the large size chip generates concentrated hot spot which is difficult to cool down. Moreover, the prior art LED is difficult to be integrated with other multiple chips.

### SUMMARY OF THE INVENTION

A main objective of the present invention is to provide a planar flip bonded & small chips integrated LED chip and its manufacture method, which can reduce the manufacture cost, provide good cooling efficiency and is good for integration.

A planar flip bonded & small chips integrated LED chip of the present invention comprises a plurality of LED bare chips and silicon substrates; the LED bare chip comprising a substrate, a N type epitaxial layer, and a P type epitaxial layer; the silicon substrate having two separated deposited metal layers facing each LED bare chip; the P type epitaxial layer and the N type epitaxial layer being separately flip welded on the metal layers via solder balls; and is characterized in that: the contact areas of the metal layers and the silicon substrate separately has a doped isolating layer I, an isolating layer II is disposed between the metal layer corresponding to each LED bare chip and the silicon substrate, the plurality of LED bare chips are connected via the metal layers and forms an anode contact and a cathode contact.

The plurality of LED bare chips are connected with each other in parallel, or in series, or in parallel and series.

The planar flip bonded & small chips integrated LED chip further has a protecting layer, and the protecting layer is covered on the outside surface of the metal layers.

The back side of the silicon substrate has a heat spreader layer composed of one or several layers of metal.

The outside face of the metal layers (32, 33) is a light reflecting face.

The silicon substrate (2) is a P type or a N type, the isolating layers I (22, 23) and the silicon substrate (2) have opposite polarities, the solder balls (40, 41) are gold ball, copper ball or tin ball, and the metal layers (32, 33) are aluminum or copper or silicon aluminum alloy.

The manufacture of the planar flip bonded & small chips integrated LED chip in the present invention comprises:
(a) forming the isolating layer II: placing the silicon substrate (2) in a oxidation furnaces to grow a oxide layer on the top surface of silicon substrate 2; then a lithography process is performed on the lithography machine with a diffusion etching mask and an etching process is performed to the oxide layer with HF solution to remove the oxide layer under the etching pattern and the remaining oxide layer forms the isolating layer II (5);
(b) forming the isolating layer I: forming the isolating layers I (22, 23) having opposite polarity with the silicon substrate (2) in a diffusion furnace, alternatively, an ion implantation method can be used to implant ions having opposite polarity with the silicon substrate (2) in to the silicon substrate (2) and then the ions are driven in the silicon substrate (2) with high temperature to form a plurality of the isolating layers I (22, 23);
(c) forming the metal layer: using a sputtering process or an evaporation process to form a metal layer; performing an etching process on the lithography machine with a metal etching mask, then performing a dry etching or a wet etching process to the metal layer, and the remaining metal layer forms the metal layers (32, 33), in parallel or in series or in parallel and series, the anode electrode (80) and the cathode electrode (81);
(d) forming the protecting layer: using a CVD process to deposit a silicon oxide protecting layer; alternatively, the silicon oxide protecting layer can be replaced by a silicon nitride protecting layer, then a lithography process is performed on the lithography machine with an etching mask, and an etching process is performed to the silicon oxide with a HF solution or a dry etching process is performed to the silicon nitride layer to form openings for the solder balls;
(e) flip bonding the LED bare chip: planting the gold balls in the opening on the protecting layer and an ultrasonic bonding process is performed to assemble every LED bare chip (1) on the gold balls; the gold balls can be replaced by copper balls or tin balls; and when tin balls are utilized, a solder reflow machine is used to flip assemble the plurality of LED bare chip 1 on the tin balls.

Other objects, advantages, and novel features of the invention will become more apparent from the following detailed description when taken in conjunction with the accompanying drawings.

### BRIEF DESCRIPTION OF THE DRAWINGS

FIG. 1 is a layout structure schematic drawing of a first embodiment of the present invention.

FIG. 2 is a circuit drawing of the LED integrated chip shown in FIG. 1.

FIG. 3 is a layout structure schematic drawing of a second embodiment of the present invention.

FIG. 4 is a circuit drawing of the LED integrated chip shown in FIG. 3.

FIG. 5 is a layout structure schematic drawing of a third embodiment of the present invention.

FIG. 6 is a circuit drawing of the LED integrated chip shown in FIG. 5.

FIG. 7 is a layout structure schematic drawing of a second embodiment of the present invention.

FIG. 8 is a circuit drawing of the LED integrated chip shown in FIG. 7.

FIG. 9 is a cross-sectional drawing of the planar flip LED integrated chip shown in FIG. 1, FIG. 3, FIG. 5 and FIG. 7 along a line A-A according to the present invention.

FIG. 10 is a cross-sectional drawing of the planar flip LED integrated chip shown in FIG. 1 after step (a) of a manufacturing method along a line B-B according to the present invention.

FIG. 11 is a cross-sectional drawing of the planar flip LED integrated chip shown in FIG. 1 after step (b) of the manufacturing method along a line B-B according to the present invention.

FIG. 12 is a cross-sectional drawing of the planar flip LED integrated chip shown in FIG. 1 after step (c) of a manufacturing method along a line B-B according to the present invention.

FIG. 13 is a cross-sectional drawing of the planar flip LED integrated chip shown in FIG. 1 after step (d) of a manufacturing method along a line B-B according to the present invention.

FIG. 14 is a cross-sectional drawing of the planar flip LED integrated chip shown in FIG. 1 after step (d) of a manufacturing method along a line B-B according to the present invention.

FIG. 15 is a cross-sectional drawing of the planar flip LED integrated chip shown in FIG. 1 after step (e) of a manufacturing method along a line B-B according to the present invention.

### DETAILED DESCRIPTION OF THE PREFERRED EMBODIMENT

### The First Embodiment

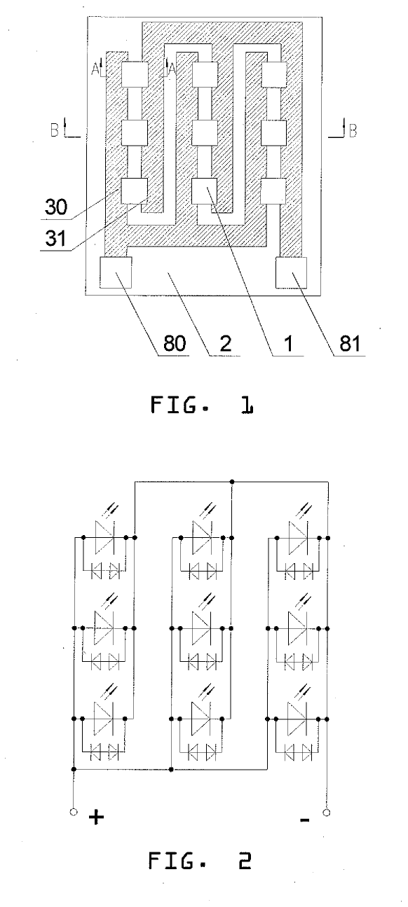

As shown FIG. 1, FIG. 2 and FIG. 9, in this embodiment, the planar flip LED integrated chip comprises 9 LED bare chips 1 and a silicon substrate 2. The LED bare chip 1 comprises a Al₂O₃ substrate 10, a GaN N type epitaxial layer 11, and a P type epitaxial layer 12. The substrate 10 can also be a SiC substrate, the silicon substrate 2 can be a P type silicon substrate, and the silicon substrate 2 has two separated deposited metal layers 32, 33 on the surface facing each LED bare chip. The metal layers 32, 33 are aluminum or copper, or silicon aluminum alloy, and the outside surface of the metal layers 32, 33 is a light reflection face, and the metal layers 32, 33 are electrodes, conductor, heat cooling sheets and light reflector. The silicon substrate 2 further has a heat spreader layer 7 composed of metal on its back side, and the heat spreader layer 7 can be made of one or multiple layers of metal. The P type epitaxial layer 12 and the N type epitaxial layer 11 are separately flip bonded on the metal layers 32, 33 via the solder balls 40, 41. The solder balls 40, 41 are gold balls, copper balls or tin ball. A bonding area between the metal layers 32, 33 and the silicon substrate 2 separately has a N type isolating layer I 22, 23 doped with phosphorus or arsenic, and an isolating layer II 5 is deposed between the metal layers 32, 33 corresponding to each LED bare chip 1 and the silicon substrate 2 and is used for isolating the metal layers 32, 33 and the silicon substrate 2 to prevent short circuit current or current leakage between the metal layer 32, 33. Furthermore, an electrostatic discharge protection diode is formed between the isolating layers I 22, 23 and the silicon substrate 2, and the electrostatic discharge protection diode can also be used to protect LED chips during the LED flip bonding process. Meanwhile, the isolating layers I 22, 23 transfer the heat from the metal layer 32, 33 given by the LED bare chip 1 to the silicon substrate 2 to provide good cooling effect. Each LED bare chip 1 is connected via the metal layers 32, 33 in parallel and has an anode electrode 80 and a cathode electrode 81; in another word, all LED bare chips 1 between the anode electrode 80 and the cathode electrode 81 are connected in parallel. The planar flip bonded & small chips integrated LED chip of the present invention further comprises a protecting layer 6, and the protecting layer 6 is covered on outside surface of the metal layer 32, 33.

Of course, the silicon substrate 2 can also be an N type silicon substrate, and the isolating layers I 22, 23 are P type the isolating layers doped with boron.

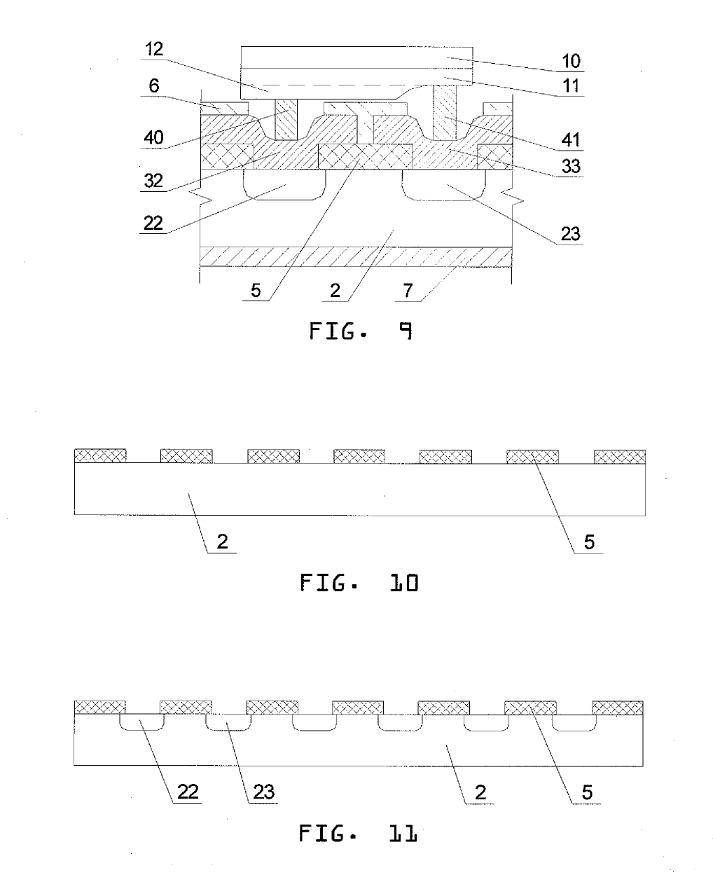

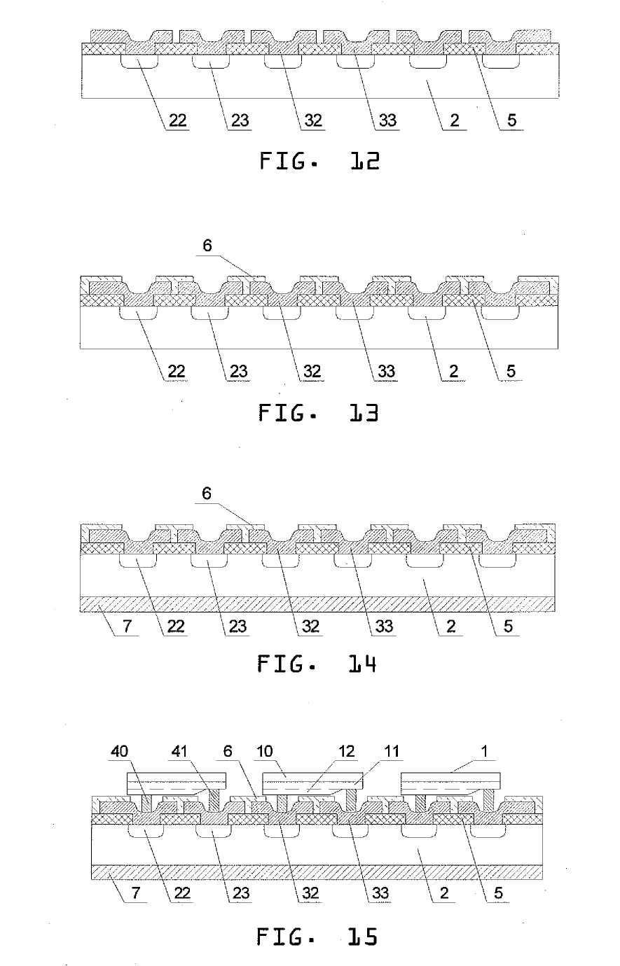

As shown in FIGS. 10-14, a manufactured method of the planar flip bonded & small chips integrated LED chip in this embodiment comprises:
(f) forming the isolating layer II: placing the silicon substrate 2 in a oxidation furnaces to grow a oxide layer with 3000 i thickness on the top surface of silicon substrate 2, the thickness range can be controlled in 1000-5000 i; then a lithography process is performed on the lithography machine with a diffusion etching mask and an etching process is performed to the oxide layer with HF solution to remove the oxide layer under the etching pattern and the remaining oxide layer forms the isolating layer II 5 , as shown in FIG. 10;
(g) forming the isolating layer I: forming the isolating layers I 22, 23 having opposite polarity with the silicon substrate 2 in a diffusion furnace, the isolating layer I 22, 23 isolates the two electrodes of the LED to avoid short circuit and current leakage, and LED bare chip 1 can transfer heat through the silicon substrate; alternatively, an ion implantation method can be used to implant ions having opposite polarity with the silicon substrate 2 in to the silicon substrate 2 and then the ions are driven in the silicon substrate 2 with high temperature to form a plurality of the isolating layers I 22, 23 as shown in FIG. 11;
(h) forming the metal layer: using a sputtering process or an evaporation process to form a metal layer having thickness 12000 i, and a thickness range of the metal layer can be controlled in 5000-40000 i; performing an etching process on the lithography machine with a metal etching mask, then performing a dry etching or a wet etching process to the metal layer, and the remaining metal layer forms the metal layers 32, 33, the anode electrode 80 and the cathode electrode 81 all being connected in parallel, as shown in FIG. 12;
(i) forming the protecting layer: using a CVD process to form a silicon oxide protecting layer having thickness 12000 i, and a thickness range of the silicon oxide protecting layer can be controlled in 8000-15000 i; alternatively, the silicon oxide protecting layer can be replaced by a silicon nitride protecting layer, then a lithography process is performed on the lithography machine with an etching mask, and an etching process is performed to the silicon oxide with a HF solution or a dry etching process is performed to the silicon nitride layer to form openings for the solder balls , as shown in FIG. 13;
(d′) forming the heat spreader layer: using metal sputtering or evaporation process to deposit an aluminum metal layer or a multiple metal layer containing titanium, nickel, and sliver on the back side of the silicon substrate 2 to form the heat spreader layer 7, as shown in FIG. 14; and
(j) flip bonding the LED bare chip: planting the gold balls in the opening on the protecting layer and an ultrasonic bonding process is performed to assemble every LED bare chip 1 on the gold ball; the gold balls can be replaced by copper balls or tin balls; and when tin balls are utilized, a solder reflow machine is used to flip assemble the plurality of LED bare chip 1 on the tin balls, as shown in FIG. 15.

### The Second Embodiment

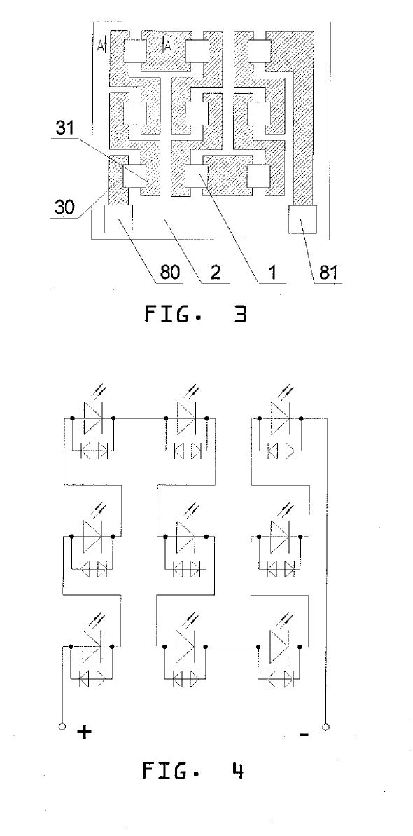

As shown in FIG. 3, FIG. 4, and FIG. 9, a main difference between this embodiment and other embodiments is: in this embodiment, each LED bare chip 1 are connected in series via the metal layer 32, 33, therefore, all the LED bare chips 1 between the anode electrode 80 and the cathode electrode 81 are connected in series.

Other characteristics of this embodiment are identical with the other embodiments.

### The Third Embodiment

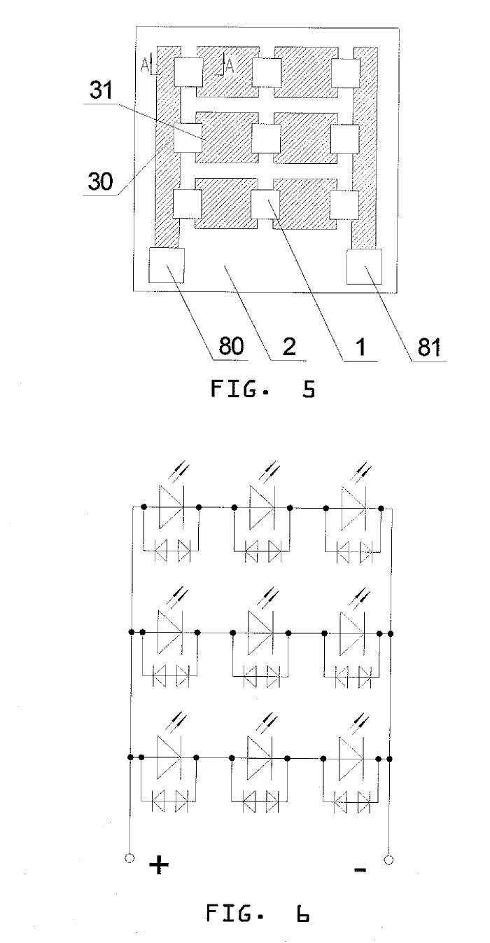

As shown in FIG. 5, FIG. 6, and FIG. 9, a main difference between this embodiment and other embodiments is: in this embodiment, each three LED bare chips 1 are connected in series as a set and then each three sets are connected in parallel.

Other characteristics of this embodiment are identical with the other embodiments.

### The Fourth Embodiment

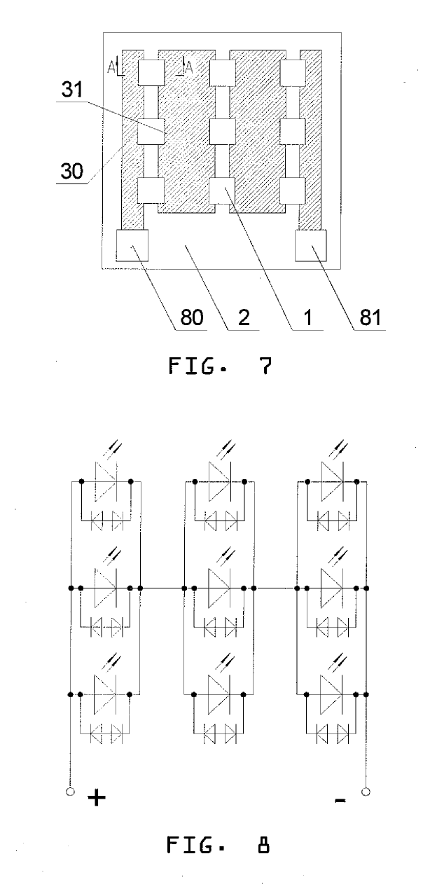

As shown in FIG. 7, FIG. 8, and FIG. 9, a main difference between this embodiment and other embodiments is: in this embodiment, each three LED bare chips 1 are connected in parallel as a set and then each three sets are connected in series.

Other characteristics of this embodiment are identical with the other embodiments.

The LED bare chip 1 included in the planar flip bonded & small chips integrated LED chip of the present invention can be other than 9 LED.

Accordingly, the present invention integrates the plurality of LED bare chips 1 on one silicon substrate 2, which can provide cooling efficiency, longer lifetime, improve lighting efficiency and reduce the cost.

The present invention can be applied in LED field. In the present invention, the plurality LED bare chips of the planar flip bonded & small chips integrated LED chip are connected to each other by the metal layers and forms the anode electrode and the cathode electrode. The plurality of LED bare chips are connected in parallel or in series. The plurality of LED bare chips cover a larger area, and have better lighting efficiency and lower manufacture cost than a power LED chip having one LED bare chip, each LED bare chip transfers heat to the metal layer via the connected two solder balls and then the isolating layer passes the heat to the silicon substrate and the heat spreader layer. The metal layer has a larger area and is able to distribute the heat better; therefore, the planar flip bonded & small chips integrated LED chip has better cooling efficiency and longer lifetime and is easier to be integrated with multiple chips. Furthermore, the outside surface of the said metal layer of the invention is a light reflecting face, light from the button side of the PN junction of LED bare chip is reflected on the metal layer. Therefore, the planar flip bonded & small chips integrated LED chip has higher lighting efficiency, and the manufacture method of the present invention can produce the planar flip bonded & small chips integrated LED chip with simple procedure and low cost.

Although the present invention has been explained in relation to its preferred embodiment, it is to be understood that many other possible modifications and variations can be made without departing from the spirit and scope of the invention as hereinafter claimed.

1. A game ticket, comprising
a substrate;
a game play area located on the substrate;
a customer key area located on the substrate;
a removable opaque covering applied to the substrate;
a first indicia configured to visually indicate to a player whether the game ticket is a winning ticket, the first indicia being located on the substrate within the game play area and concealed by the removable opaque covering; and
a second indicia configured to visually indicate to the player whether the game ticket is a winning ticket, the second indicia including
a first player key located on the substrate and concealed by the removable opaque covering; and
a second player key located on the substrate within the customer key area,
wherein whether the game ticket is a winning ticket is determinable by the player prior to the ticket being tendered for redemption using information from the first and second player keys in combination, but not determinable using only information from only one of the first and second player keys.

2. (canceled)

3. The game ticket of claim 1, wherein the first player key is located within the game play area.

4. The game ticket of claim 1, wherein the second player key is concealed by the removable opaque covering.

5. The game ticket of claim 1, wherein whether the game ticket is a winning ticket is determinable by the player based upon a comparison by the player of the first and second player keys.

6. The game ticket of claim 1, wherein
the game ticket is an instant-win lottery game ticket.

7. The game ticket of claim 1, wherein
the removable opaque covering is a scratch-off layer.

8. The game ticket of claim 1, wherein
the customer key area and the game play area are located separate and apart from one another on the substrate.

9. The game ticket of claim 1, wherein
the customer key area is located at least partially within the game play area.

10. The game ticket of claim 1, wherein
the customer key area is located entirely within the game play area.

11. The game ticket of claim 1, wherein
at least one of the first and second player keys is a non-numeric and non-alphabetic symbol.

12. The game ticket of claim 1, wherein
at least one of the first and second player keys is an alpha-numeric character.

13. The game ticket of claim 1, further comprising:
a third area located on the substrate including a code to at least one of authenticate and validate the game ticket, the code being concealed by the removable opaque covering.

14. A book comprising:
a plurality of game tickets, each having:
a substrate;
a game play area located on the substrate;
a customer key area located on the substrate;
a removable opaque covering applied to the substrate;
a first indicia configured to visually indicate to a player whether the game ticket is a winning ticket, the first indicia being located on the substrate within the game play area and concealed by the removable opaque covering; and
a second indicia configured to visually indicate to a player whether the game ticket is a winning ticket, the second indicia including:
a first player key located on the substrate and concealed by the removable opaque covering; and
a second player key located on the substrate within the customer key area,
wherein whether the game ticket is a winning ticket is determinable by the player using information from the first and second player keys in combination but not separately and a position of the first player key within the game play area cannot be determined by visual inspection of the ticket prior to removal of the removable opaque covering.

15. The book of claim 14, wherein
the position of the first player key within the game play area floats from game ticket to game ticket in the book.

16. A method of playing a game of chance, comprising:
receiving, by a player, a game ticket having a first indicia configured to visually indicate to the player whether the game ticket is a winning ticket, the game ticket also having a first player key and a second player key, the first indicia and the first player key concealed by a removable opaque covering, the first and second player keys configured, in combination with each other, configured to visually indicate to the player whether the game ticket is a winning ticket without providing sufficient information separately to indicate whether the game ticket is a winning ticket;
removing the opaque covering from a game play area to reveal the first indicia;
removing the opaque covering to reveal the first player key; and
prior to the ticket being tendered for redemption, using information from the first player key and a second player key in combination to visually determine if the game ticket is a winning ticket.

17. The method of claim 16, further comprising:
removing an opaque covering from a customer key area separate and apart from the game play area to reveal the second player key; and
comparing the first player key with the second player key to visually determine if the game ticket is a winning ticket.

18. The method of claim 16, wherein
the game ticket is an instant-win lottery game ticket.

19. The method of claim 16, further comprising:
receiving a prize if the first player key matches the second player key.

20. The method of claim 16, further comprising:
tendering the game ticket for redemption of a prize.

21. The method of claim 16, further comprising:
removing an opaque covering from a third area of the game ticket to void the ticket.

22. A method for facilitating the play of a game, comprising:
providing a first player key in a first area of a game ticket;
providing a second player key in a second area of the game ticket;
providing game play information in a game play area on the game ticket, wherein whether the game ticket is a winning ticket is determinable by a player upon visual examination of the first and second player keys in combination, but not separately, and is also determinable by a player upon visual examination of the game play information;
concealing the first player key and the game play information with a removable opaque coating; and
offering the game ticket for sale.

23. The method of claim 22, wherein the first area is located in within the game play area.

24. The method of claim 22, further comprising:
concealing the second player key with the removable opaque coating.

25. The method of claim 22, wherein
the game ticket is an instant-win lottery ticket.

26. The method of claim 22, wherein
the removable opaque covering is a scratch-off coating.

27. The method of claim 22, wherein whether the game ticket is a winning ticket is determined by:
removing the removable opaque coating of the game play area so that the first player key is exposed; and
comparing the first player key with the second player key.

28. The method of claim 22, wherein
the game ticket is a winning ticket if the first player key matches the second player key.

29. The method of claim 22, wherein
at least one of the first and second player key is a non-numeric and non-alphabetic symbol.

30. The method of claim 22, wherein
at least one of the first and second player key is an alpha-numeric character.

31. The method of claim 22, further comprising:
providing a prize upon a tendering of a valid winning game ticket for redemption.

32. The method of claim 22, further comprising:
providing a code within a third area of the game ticket to at least one of authenticate and validate the game ticket, the code being concealed by the removable opaque coating.

33. An article of manufacture comprising a computer-readable medium having stored thereon instructions adapted to be executed by a processor, the instructions which, when executed, define a series of steps to be used to control a method for facilitating validation of a game ticket, the method comprising:
providing a ticket having a first and second indicia concealed by a removable opaque covering, the first and second indicia each separately indicating to a player whether the ticket is a winning ticket, the first indicia being located within a game play area and the second indicia including a first player key located within the game play area and a second player key located within a customer key area,
wherein whether the game ticket is a winning ticket is determinable by the player using information from the first and second player keys in combination, but not from either of the player keys alone.

34. A method for facilitating the play of a game, comprising:
providing a game ticket to a player, the game ticket having
a first player key in a first area of a game ticket,
a second player key in a second area of the game ticket,
a game play area;
receiving a tender of the game ticket for a prize; and
paying the prize to the player,
wherein, whether the game ticket is a winning ticket is determinable by the player based upon visual examination of game play area and is also determinable by the player based upon visual examination of the first and second player keys in combination, but not from either of the player keys alone.

35. The method of claim 34, wherein the first player key by itself does not provide enough information to determine whether the game ticket is a winning ticket, and the second player key by itself does not provide enough information to determine whether the game ticket is a winning ticket.

36. The method of claim 35, wherein the game ticket is a scratch-off instant win lottery ticket.
